(19) United States
(12) Patent Application Publication
(10) Pub. No.: US 2024/0297136 A1
(43) Pub. Date: Sep. 5, 2024

(54) METHOD FOR PRODUCING SOLDER BUMPS ON A SUPERCONDUCTING QUBIT SUBSTRATE

(71) Applicant: IMEC VZW, Leuven (BE)

(72) Inventors: Jaber Derakhshandeh, Tienen (BE); Vadiraj Manjunath Ananthapadmanabha Rao, Leuven (BE); Danny Wan, Leuven (BE); Eric Beyne, Heverlee (BE); Kristiaan De Greve, Heverlee (BE); Anton Potocnik, Leuven (BE)

(21) Appl. No.: 18/591,705

(22) Filed: Feb. 29, 2024

(30) Foreign Application Priority Data
Mar. 1, 2023 (EP) 23159311.2

(51) Int. Cl. H01L 23/00; H10N 60/01; H10N 60/81

(52) U.S. Cl. CPC H01L 24/11; H01L 24/05; H01L 24/13; H10N 60/0912; H10N 60/815; H01L 2224/0401; H01L 2224/11009; H01L 2224/11462; H01L 2224/13109

(57) ABSTRACT

Superconducting solder bumps are produced on a qubit substrate by electrodeposition. The substrate comprises qubit areas, and superconducting contact pads connected to the qubit areas. First a protection layer is formed on the substrate, and patterned so as to cover at least the qubit areas. Then one or more thin layers are deposited conformally on the patterned protection layer, the thin layers comprising at least a non-superconducting layer suitable for acting as a seed layer for the electrodeposition of the solder bumps. The seed layer is removed locally in areas which lie within the surface area of respective contact pads. This is done by producing and patterning a mask layer, so that openings are formed therein, and by removing the seed layer from the bottom of the openings. The solder bumps are formed by electrodeposition of the solder material on the bottom of the openings. After the formation of the solder bumps, the seed layer and the protection layer are removed.

### CROSS-REFERENCE TO RELATED APPLICATIONS

The present application is a non-provisional patent application claiming priority to European Patent Application No. EP 23159311.2, filed on Mar. 1, 2023, the contents of which are hereby incorporated by reference.

### FIELD OF THE DISCLOSURE

The present disclosure is related to the formation of interconnect bumps on a substrate comprising superconducting qubits or parts thereof.

### BACKGROUND

3D integration of microchips involves the bonding and interconnecting of multiple stacked chips, and/or the bonding and interconnecting of a chip to a larger carrier component such as an interposer or a printed circuit board (PCB). In the field of superconducting (SC) quantum qubits, there is a special interest in 3D integration, as it enables increases in the number and density of qubits by interconnecting the qubits or parts thereof by vertical interconnects. Such vertical interconnects include TSV (through substrate via) connections through the substrate of a qubit chip and/or through an interposer chip. The interconnects between bonded quantum components, for example a chip and an interposer, may be realized by solder bump connections.

Superconducting qubit devices often benefit from the use of materials having superconducting properties at the cryogenic operational temperature. This is true for the materials used in the qubits as such and also for the TSVs, for any lateral conductors that connect the qubits to the TSVs, and for the solder bumps that contact the TSVs and/or the lateral conductors. Suitable materials include Al, Ta, TaN, Ti, TiN, TiW, Ru, Zr, ZrN, Mo, In, Nb, NbTi, NbN, NbTiN, Nb₃Al, and others. A suitable material for the solder bumps is indium. Patent publication document US2020/0176409 for example describes the deposition of indium bumps on a TiN diffusion-barrier layer formed on Al contact pads of a superconducting qubit wafer. The technique described for the formation of the indium bumps is the so-called lift-off technique, wherein a patterned photoresist layer is formed on the qubit wafer, with the pattern defining openings in the resist at the location of the bumps. This is followed by the deposition of indium in the openings and on the resist. The resist is then stripped, leaving indium bumps at the locations of the openings. This lift-off technique is however expensive and only applicable for large bump dimensions. The technique is also not applicable on large wafer sizes such as on standard Si process wafers of 300 mm in diameter.

Electrodeposition may be used to facilitate scalability toward smaller bumps arranged in higher density arrays and toward the use of larger wafers. This technique is, however, problematic in the context of SC materials, given that it may be predicted on the presence of a low resistive seed layer on the wafer. Often copper is used for this seed layer, but as copper is not a superconducting material, it cannot be used in this way in a SC qubit context. Plating indium directly on a seed layer formed of SC material is also difficult, given that SC materials have very high resistivity at the temperatures applicable for the electrodeposition. As a consequence, bump height will depend on the position of the bump on the wafer: bumps will be higher in lateral areas of the wafer compared to the centre.

Direct electrodeposition of indium on SC layers is challenging due to the formation of native oxide on SC layers that is not dissolved in the plating chemistry. The compatibility of the electrodeposition process with qubits is another challenge. Many electrodeposition processes are likely to damage the already processed qubit structures.

### SUMMARY

In some embodiments of the present disclosure, superconducting solder bumps are produced on a qubit substrate by electrodeposition. The substrate comprises qubit areas, each area comprising a superconducting qubit or parts thereof, and the substrate further comprises superconducting contact pads connected to the qubit areas. First a protection layer is formed on the substrate and patterned so as to cover at least the qubit areas. Then one or more thin layers are deposited conformally on the patterned protection layer, the thin layers comprising at least a non-superconducting layer suitable for acting as a seed layer for the electrodeposition of the solder bumps. If more than one thin layer is conformally deposited, e.g., forming a stack of layers, the stack comprises one or more layers of superconducting material and the non-superconducting seed layer forms the top layer of the stack. The seed layer is then removed locally in areas which lie within the surface area of respective contact pads. This is done by producing and patterning a mask layer, so that openings are formed therein, and by removing the seed layer from the bottom of the openings. The solder bumps are formed by electrodeposition of the solder material on at least part of the bottom of the openings. This may be realized by depositing the solder in the openings directly. Alternatively, it may be realized by first removing the mask layer and forming a second mask layer patterned so as to form openings lying within the surface areas of the first openings. After the formation of the solder bumps, the first or second mask layer, the seed layer and the protection layer are removed.

The seed layer conducts current toward the openings at the bottom of which the solder bumps are formed during the electrodeposition. As the seed layer is a non-superconducting layer, it can be realized as a layer that is suitable for this particular purpose of conducting current, i.e. a layer of low resistivity at a temperature applicable during electrodeposition, such as a copper layer, enabling to form solder bumps at the same deposition rate regardless of the position of the bumps on the wafer. Bumps of essentially equal height can thereby be formed regardless of whether the bump locations are closer to or further from the edge of the wafer. At the same time, as the seed layer is first removed locally, and completely removed after the bump formation, no or very little of the seed layer material enters the solder bumps so that the superconducting properties of the bumps are maintained. The method involves multiple lithography and etch steps, which are however not detrimental to the qubit areas, as these areas are protected by the patterned protection layer. This may be an organic layer that is removable by a solvent selectively with respect to the qubit metals.

The present disclosure includes a method for producing solder bumps formed of a superconducting solder material on a substrate, the substrate comprising: (i) a plurality of superconducting qubits or parts thereof, (ii) a plurality of contact pads formed of superconducting material, each pad being electrically connected to one or more of the qubits or qubit parts, the method comprising: (i) producing a protection layer on the substrate and patterning said protection layer so that the qubits and/or qubit parts are covered by the protection layer, while the contact pads are at least partially exposed, wherein the patterned protection layer has a given topography, (ii) producing a non-superconducting seed layer on the substrate, said seed layer following the topography of the patterned protection layer, said seed layer being suitable as an electrically conductive layer that enables to conduct current in an electrodeposition process, (iii) producing a mask layer on the seed layer, and patterning the mask layer so as to form openings therein, the surface area of said openings lying within respective exposed areas of the contact pads, (iv) removing the material of the seed layer from the bottom of said openings, (v) thereafter, depositing the superconducting solder material by electrodeposition on the bottom of the respective openings thereby forming the solder bumps, (vi) removing the mask layer, and (vii) after the electrodeposition, removing the seed layer and the protection layer.

In the method set out in the previous paragraph, the steps are not necessarily performed in the sequence in which they are listed, unless explicitly stated or implicitly clear from the applied wording. In particular, the step of removing the mask layer does not necessarily take place after the electrodeposition step. As will be described in the detailed description, the removal of the mask layer may be followed, according to some embodiments, by the formation and patterning of a second mask layer defining smaller openings than the first openings, after which the solder is deposited on the bottom of smaller openings. In the above formulation therefore, the electrodeposition can be said to be performed to the effect that the solder material is deposited on at least part of the bottom of the openings in the mask layer, after the removal of the seed layer in the openings.

According to an embodiment, the electrodeposition step is performed directly after the removal of the material of the seed layer from the bottom of the openings, so that the seed layer contacts the bumps in a peripheral area thereof, and the mask layer is removed after the formation of the solder bumps.

According to another embodiment: (i) the mask layer is a first mask layer and the openings formed therein are first openings, (ii) the first mask layer is removed after the step of removing the material of the seed layer from the bottom of the first openings, and (iii) after removing the first mask layer, a second mask layer is produced, wherein the second mask layer is patterned so as to form second openings therein, the surface area of the second openings lying within the surface area of the respective first openings, so that the seed layer is separated from the bottom of the second openings by the material of the second mask layer,
the electrodeposition step is performed directly after the formation and patterning of the second mask layer, on the bottom of the second openings, so as to form solder bumps which are not in contact with the seed layer,
the second mask layer is removed after the formation of the solder bumps, followed by the removal of the seed layer and of the protection layer.

According to an embodiment, the method further comprises the step of producing a layer of superconducting material directly on the substrate after the formation and patterning of the protection layer and prior to the formation of the seed layer, the layer of superconducting material following the topography of the patterned protection layer, so that the layer of superconducting material is exposed at the bottom of the openings, and the solder material is deposited on the layer of superconducting material, wherein the layer of superconducting material outside the bumps is removed after the removal of the seed layer.

According to an embodiment, the layer of superconducting material is a barrier layer configured to stop diffusion of solder material into the contact pads.

According to an embodiment, the protection layer is patterned so as to form openings therein, the surface area of the openings lying within the surface area of the contact pads.

In the latter embodiment, the surface area of the openings in the mask layer may be lying within the surface area of the openings in the protection layer. Alternatively, the surface area of the openings in the mask layer may be larger than the surface area of the openings in the protection layer, so that the openings in the mask layer fully overlap the openings in the protection layer.

According to an embodiment, the protection layer is patterned so as to cover only the qubits or parts thereof.

The method may further comprise the production of a plurality of spacer bumps.

According to embodiments of the present disclosure, the seed layer is formed of copper and/or the solder material is indium.

### BRIEF DESCRIPTION OF THE FIGURES

The above, as well as additional objects, features, and benefits, may be understood through the following illustrative and non-limiting detailed description, with reference to the appended drawings. In the drawings like reference numerals will be used for like elements unless stated otherwise.

FIG. 1 shows a top view of a superconducting qubit wafer, and an enlarged image of a region comprising an array of qubit areas, according to an example embodiment.

FIG. 2 is a section view of a portion of the enlarged region, comprising three adjacent qubit areas, according to an example embodiment.

FIG. 3 illustrates the formation of a protection layer on the qubit wafer, according to an example embodiment.

FIGS. 4, 5, 6, 7, 8, 9, 10, 11, 12, 13, and 14 illustrate aspects of a method, according to a first example embodiment.

FIGS. 15, 16, 17, 18, and 19 illustrate a second example embodiment of a method.

FIGS. 20, 21, 22, 23, 24, 25, 26, 27, and 28 illustrate a third example, embodiment of a method.

FIGS. 29, 30, and 31 illustrate a fourth example embodiment of a method.

FIGS. 32, 33, 34, 35, 36, and 37 illustrate the formation of spacer bumps combined with the method illustrated in FIGS. 4-14, according to an example embodiment.

FIGS. 38 and 39 illustrate the bonding process of two qubit components, each comprising spacer bumps and solder bumps, according to an example embodiment.

All the figures are schematic, not necessarily to scale, and generally only show parts to elucidate example embodiments, wherein other parts may be omitted or merely suggested.

### DETAILED DESCRIPTION

In the following detailed description, all references to specific materials and dimensions are included by way of example only, and none of these citations are to be construed as limitations of the protection scope.

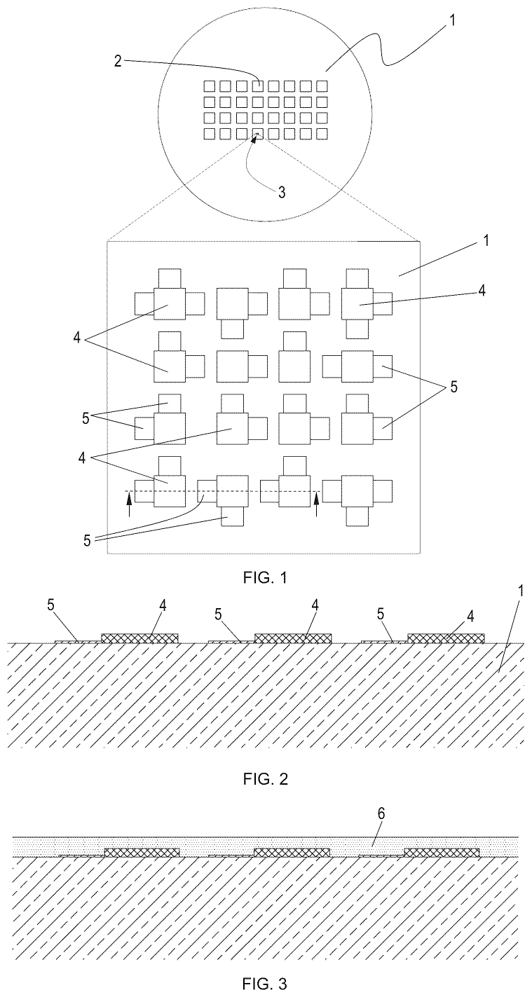

FIG. 1 shows a top view of a superconducting qubit wafer 1, defined in the present context as a substrate destined to be divided into a plurality of SC qubit chips and/or qubit interposer chips. The outline of a number of such qubit chips 2 is indicated. The wafer 1 may be a silicon process wafer of diameter 200 mm or 300 mm. Within the surface area of the chips 2, SC qubit elements have been processed according to specific layouts. On the scale of the top view of the full wafer 1, these elements are not distinguishable. Therefore, a square 3 of about 1×1 mm is represented in an enlarged view. On this square area, 16 SC qubit areas 4 have been processed, arranged in a regular 2-dimensional array. A qubit area 4 may contain all the elements of an SC qubit, such as a Josephson junction, a capacitor, a waveguide, and a resonator. These elements are not shown. A variety of fabrication methods may be used to produce these elements. Some or all of the qubit areas 4 could contain only parts of an SC qubit, to be connected or capacitively coupled to the remaining parts processed on a second qubit wafer or chip that is to be bonded to the illustrated wafer by solder bonding.

Contact pads 5 are illustrated also in the enlarged view in FIG. 1. These are represented as patches of superconducting material, for example Al, electrically connected to a qubit area 4. These contact pads 5 are configured to receive solder bumps thereon via a variety of methods, which a number of embodiments of which are described herein. The representation of the contact pads 5 as rectangular areas adjacent the qubit areas 4 does not necessarily correspond to a realistic representation of the contact pads. It is intended merely to give a rough indication of possible locations of the solder bumps relative to the qubit areas 4. For example, there may additionally be conductors on the wafer surface which interconnect a number of qubit areas and/or which connect contact pads to one or more qubit areas not directly adjacent the contact pads. Such layouts are not shown in the drawings.

FIG. 2 is a section view of three qubit areas 4 and respective contact pads 5 connected thereto. The represented thickness of these areas is not necessarily in accordance with realistic qubit elements and conductors and intended only to visualize the location of the areas in question. The qubit areas 4 and contact pads 5 are shown as being in direct contact with the Si wafer 1. In reality these elements could be formed on one or a stack of intermediate layers formed on the Si.

A protection layer 6 is produced on the qubit wafer, as illustrated in FIG. 3, covering the qubit areas 4 and contact pads 5. This is a layer that can be patterned by lithography alone or by lithography and etching. The protection layer 6 is removable without damaging the qubit elements in the areas 4. In some embodiments, it is an organic photoresist layer, removable by a solvent.

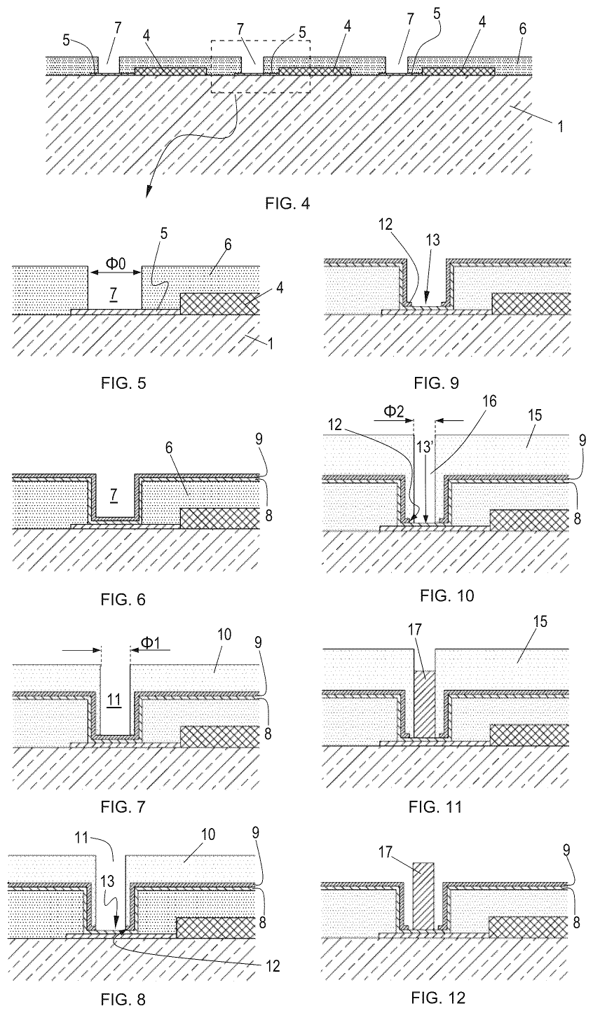

A first embodiment of a method of the present disclosure is described with reference to FIGS. 4 to 12. As seen in FIG. 4, the protection layer 6 is patterned. In the case of a photoresist layer, this may be done by illuminating the layer 6 through a lithographic mask, developing the layer and removing illuminated or non-illuminated areas depending on the type of resist used for layer 6. In the embodiment shown, the pattern comprises openings 7 in the protection layer 6, the surface area of the openings 7 lying within the surface area of respective contact pads 5. The openings 7 define future positions of solder bumps. The pattern may include additional openings which are not aligned to contact pads 5 and which are intended to define the location of spacer bumps. In the exemplary embodiment shown, the openings 7 have a circular cross-section with a diameter ϕ0 in the order of 20 to 30 μm. Other dimensions and shapes are however possible. The patterning step results in the protective layer 6 having a topography defined by the openings 7.

FIG. 5 is an enlarged detail of an area comprising one of the openings 7 formed in the protection layer 6. The steps described hereafter are performed across the full qubit wafer, i.e., on each of the contact pads 5 which are to receive a solder bump thereon.

In the following, specific materials are cited for a number of elements and/or layers. These materials are merely intended as examples on the basis of which the present disclosure is described, and indications will be given as to other applicable materials later in this description.

In the exemplary configuration described hereafter, the metal used for the Josephson junctions and other qubit elements in the qubit areas 4 and for the contact pads 5 is aluminium, known to have superconducting properties at the cryogenic operational temperature of an SC qubit processor. With reference to FIG. 6, a thin diffusion barrier layer 8, which may be formed for example of TiN or TiW, is deposited conformally on the full wafer surface, i.e. this layer follows the topography of the patterned protection layer 6, so that the barrier layer 8 is deposited on the sidewalls and bottom of the openings 7 as well as on the upper surface of the protection layer 6. Like Al, this barrier layer has superconducting properties at the SC qubits' operational temperature. Layer 8 will serve as a diffusion barrier between SC layers of the qubit and the indium solder bump to prevent consumption of solder and qubit SC metal over the product time (shelf life) and during possible next processing steps such as bonding. The barrier layer 8 may be between 10 and 100 nm in thickness for example. As the diameter of openings 7 is 20-30 μm, the thickness of layer 8 as represented in the drawing is much higher than 100 nm, in order to visualize the layer, but in reality, this layer is much thinner than shown, in comparison with the dimensions of the openings 7.

Then a copper layer 9 is conformally deposited on top of the barrier layer 8, having a thickness in the same order of magnitude as the barrier layer. Copper is a non-superconducting material, and has very low resistivity at room temperature. The copper layer is therefore suitable to serve as a seed layer for electrodeposition of the solder bump material. The barrier and Cu layers 8 and 9 cover the wafer completely, up to the edge of the wafer 1.

The barrier and Cu layers 8 and 9 may be deposited by a variety of techniques, such as physical vapour deposition (PVD) or chemical vapour deposition (CVD), for example applied in the same reactor without breaking the vacuum, so that oxide formation on the barrier layer 8 is minimized.

Then a second photoresist layer 10 is formed on the wafer, and patterned, as illustrated in FIG. 7. This resist layer will hereafter be referred to as a mask layer, in accordance with the terminology used in the appended claims. Instead of a resist layer, it could be any layer that is patternable by lithography and/or etching. The pattern of this mask layer 10 contains openings 11 above the contact pads 5. The surface area of the openings 11 lies within the surface area of the contact pads 5 and within the surface area of the bottom of the openings 7 in the protection layer 6, which are now lined with the barrier and Cu layers 8 and 9. In the embodiment shown, the openings 11 have a circular cross-section having a diameter ϕ1 that is smaller than ϕ0. The difference between ϕ0 and ϕ1 may be in the order of 1 μm or smaller depending on the litho tool overlay accuracy.

With reference to FIG. 8, the Cu is then removed from the bottom of the openings 11 in the mask layer 10 by a suitable etch process. This may be a wet etch process configured to remove the Cu essentially anisotropically, so that the Cu remains under the mask layer 10. After the Cu etch, the Cu layer 9 is exposed along a ring-shaped area 12 around the periphery of the bottom 13 of the openings 11, the surface of the bottom being formed of material of the barrier layer 8. The Cu etch process may be selective to the barrier layer 8, so that the process stops on this layer 8. Alternatively, a timed etch is used based on the known thickness of the Cu layer 9. In any case, the wet etch is configured also to remove any native oxides from the barrier layer 8 on the bottom 13 of the openings 11.

Then the mask layer 10 is stripped, as illustrated in FIG. 9, which is followed by the formation and patterning of a second mask layer 15, illustrated in FIG. 10. The pattern of the second mask layer contains openings 16 whose surface area lies within the surface area of the openings 11 in the first mask layer 10, i.e. within the surface area of the bottom 13 of the first openings 11. The diameter of the second openings ϕ2 is smaller than the diameter of the first openings ϕ1, the difference between ϕ1 and ϕ2 being in the order of 1 μm or smaller depending on the litho tool overlay accuracy. As is visualised in FIG. 10, this means that the material of the second mask 15 now separates the ring 12 of Cu from the bottom 13′ of the second openings 16.

The wafer may then be subjected to a cleaning treatment which may be done by exposure to O₂ plasma for example, for removing any residuals remaining after the patterning of the second mask layer 15. If the second mask layer 15 is hydrophobic, the O₂ plasma treatment renders this mask layer 15 hydrophilic, allowing the wafer to be used in the subsequent electroplating process.

With reference to FIG. 11, electroplating is then performed, using indium as the solder material in an electroplating tool. In such a tool, the wafer is contacted from the sides at a plurality of contact points along the wafer's circumference, from which a current flows through the Cu seed layer 9, while the wafer is submerged into an electrolytic bath comprising an indium-containing electrode or an inert electrode combined with an indium-containing electrolyte solution. Indium ions are attracted to the exposed surface at the bottom 13′ of the openings 16 and form an indium solder bump 17 thereon, as illustrated in FIG. 11. This embodiment facilitates the use of this process for the formation of superconducting solder bumps 17 of equal height on a SC qubit wafer, without any copper entering the solder bumps 17. During the electrodeposition process, the Cu seed layer 9 forms a low resistive path for the electrodeposition current across the full surface of the wafer, enabling the deposition of indium at the same rate on all the bump locations, so that all the bumps essentially have the same height at the end of the electrodeposition process. While the Cu seed layer 8 enables this formation of indium bumps at the same rate across the wafer, there is no direct contact between the Cu and the indium bumps, because of the difference in diameters ϕ1 and ϕ2: because of this difference, the material of the second mask 15 separates the ring 12 of Cu from the bottom 13′ of the openings 16. In this way, no copper nor any copper-containing intermetallic compounds are included in the bumps 17. The indium bump height can for example be between 5 μm and 50μ m depending on the desired gap between two bonded dies or wafers.

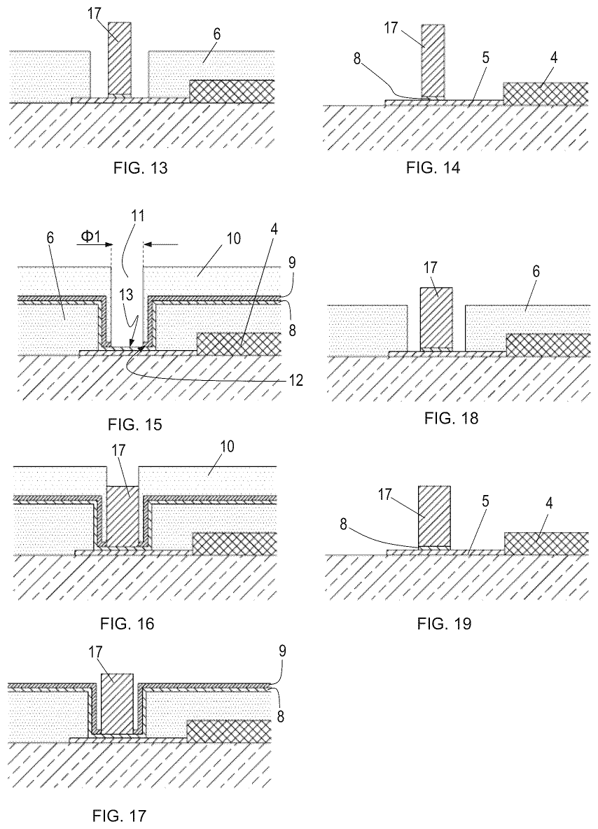

After the bump formation, the second mask layer 15 is stripped, as illustrated in FIG. 12. Thereafter, the Cu layer 9 and the barrier layer 8 are removed outside the bumps 17 by wet etching selectively with respect to the indium bumps 17, as illustrated in FIG. 13. The etching of the barrier layer 8 is also selective relative to the qubit SC layer of the contact pads 5. In the final step, the protection layer 6 is removed by a solvent, as illustrated in FIG. 14, leaving the bumps 17 in electrical contact with the contact pads 5 via a remaining portion of the barrier layer 8 and ready to be bonded to corresponding bumps on a second wafer or chip.

As stated, the embodiment described above is configured so that no copper enters the bumps 17. According to other embodiments, a limited direct contact between the copper and the solder material during electrodeposition is allowed or even desirable, as will be explained hereafter. Such an embodiment is first described as an alternative to the first embodiment, using the same materials and dimensions. The elements of the method according to this second embodiment are the same as in the previous embodiment, up to the point where the Cu is removed in the openings 11 in the first mask layer 10, exposing the bottom 13 of the openings 11, the surface of the bottom 13 being formed of barrier layer material. This situation is represented again in FIG. 15. Now however, instead of removing the first mask 10 and depositing a second mask, the electrodeposition step is performed on the configuration shown in FIG. 15. For example, an O₂ plasma treatment may first be performed for cleaning bottom 13 and rendering the mask layer 10 hydrophilic. The electrodeposition is then performed, resulting in the bumps 17 of diameter ϕ1, as illustrated in FIG. 16, followed by the removal of the mask layer 10, the wet etching of layers 8 and 9 and the removal by a solvent of the protection layer 6, as illustrated in FIGS. 17 to 19. The difference with the previous embodiment is that the bumps 17 are in direct contact with the Cu ring 12 circumventing the bottom 13 of the openings 11. This has an influence on the plating process, in that the formation of indium is initiated not only on the bottom 13, but also along the circumference of the Cu ring 12, leading to the formation of copper and/or copper-containing intermetallic compounds in a lower peripheral area of the bump, together with the formation of pure indium in the central area of the bump. As long as the central area is wide enough (e.g., between 2μ m and 100μ), the presence of the Cu-containing peripheral area does not significantly deteriorate the superconducting characteristics of the bump. Whether or not this embodiment is applicable may therefore depend on the dimensions of the bumps, the type of barrier layer material and on the degree of copper formation in the bumps.

In some cases, however, the exposure to copper is useful in order to initiate the plating process. For example, plating of indium directly on aluminium is not generally possible, so if the surface area of the bottom 13 of openings 11 is formed of aluminium, or if no barrier layer is applied, the exposure of the Cu ring 12 may be used to initiate the electrodeposition. For larger bump sizes, this can lead only inclusion of copper in only a peripheral area of the bump, which will therefore not deteriorate the superconducting properties of the bump in a significant manner.

In either one of the embodiments described above, the diameter ϕ1 of the openings 11 could be larger than the diameter ϕ0 of the openings 7, and overlapping the diameter ϕ1. In that case, the copper would be removed not only at the bottom of the openings 11 but also from the sidewalls and from a ring-shaped area on top of the protection layer 6. If only one mask is used as in the embodiment of FIGS. 15-19, this would lead to a mushroom shaped bump 17, which may be acceptable depending on the overall bump dimensions. This embodiment would allow the removal of the copper and the barrier material to occur after the bump formation, preventing such processes from adversely affecting the SC contact pad 5. This variant is not always possible, for example in cases where the ring of Cu 12 is needed at the bottom of the opening 11 in order to initiate the electrodeposition of the solder material, as in the case of indium solder deposited in openings 11 having Al on the bottom surface.

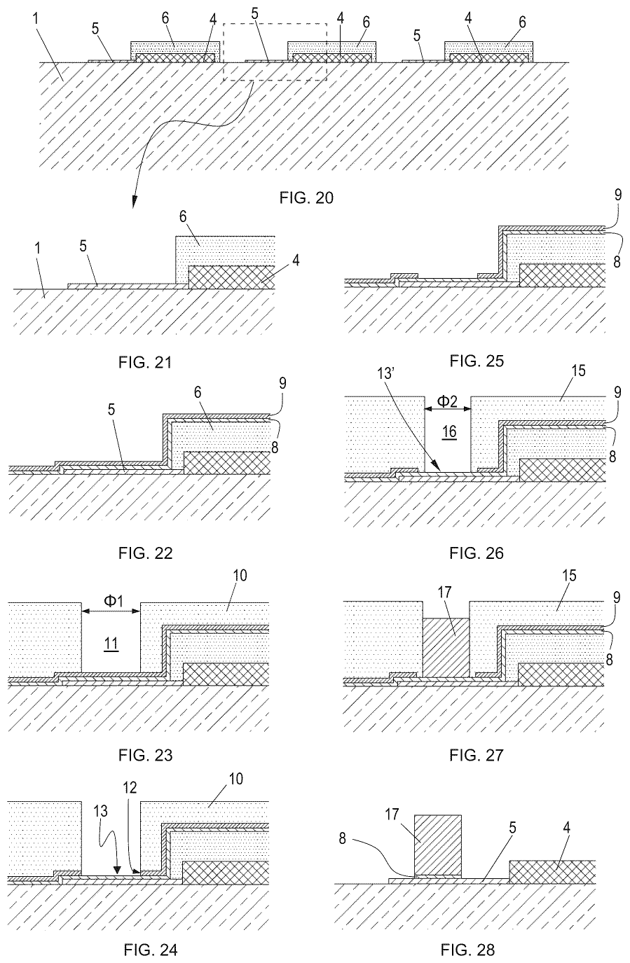

A third embodiment of the method of the present disclosure is illustrated in FIGS. 20 to 28. As seen in FIG. 20, the protection layer 6 is now patterned in a different way compared to the previous embodiments, leading to a different topology of the patterned layer 6. The material of the protection layer 6 is removed everywhere except on the qubit areas 4, i.e., the contact pads 5 are left essentially exposed. Apart from this, the remaining steps are similar to the first embodiment: the conformal deposition of the barrier and Cu layers 8 and 9 (FIG. 22), the formation and patterning of the first mask layer 10, comprising openings of diameter ϕ1 above the contact pads 5 (FIG. 23), the removal of Cu from the bottom of the openings 11 (FIG. 24), leaving a ring 12 of Cu around the circumference of the bottom 13, the stripping of the first mask layer 10 (FIG. 25), the formation and patterning of the second mask layer 15, comprising openings 16 above the contact pads, the openings 16 having a diameter ϕ2<ϕ1, the electrodeposition step (e.g., after O₂ plasma treatment) to form the bumps 17 (FIG. 27), and the removal of the second mask layer 15, the wet etching of Cu and barrier layers 9 and 8 outside the bumps 17, and the removal by solvent of the protection layer 6 (FIG. 28).

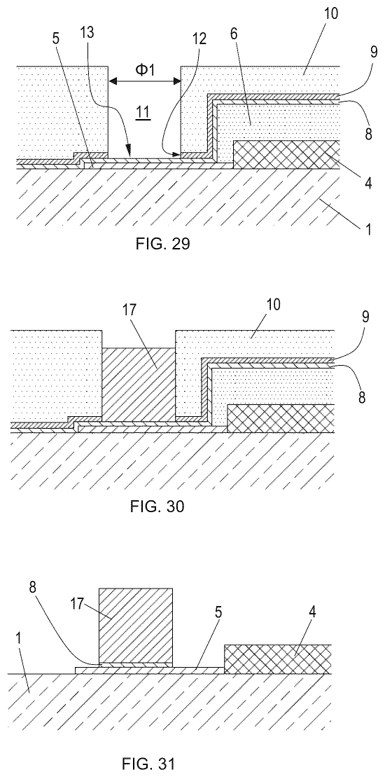

A variation is illustrated in FIGS. 29 to 31: the electrodeposition is done after forming the first mask layer 10 and openings 11, i.e., with the Cu ring 12 contacting the indium bumps 17, so that Cu enters the bumps in a peripheral area thereof. Again, the latter embodiment is acceptable depending on the dimensions and materials chosen, for example for certain material combinations, such as the electrodeposition of indium on aluminium.

As stated above, the scope of the present disclosure is not limited to the cited materials. In the description of the above embodiments for example, Al may be replaced by other suitable superconducting materials, and Cu may be replaced by other suitable non-superconducting low-resistive metals such as Pt and Au, among other possibilities.

Likewise, the present disclosure is applicable for the formation of solder bumps within a wide range in terms of their lateral dimensions, i.e. the diameter in case of bumps having a circular cross-section or for example the length of the diagonal in case of bumps having a rectangular cross-section. For example, circular bumps of diameters between about 2 μm and about 50 μm are obtainable by the various embodiments of the present disclosure. The actual size depends on the desired layout and connectivity of the stacked SC qubit chips. The smaller bumps of this range can be placed close together to form high density arrays of solder bumps, which cannot be achieved with the lift-off technique.

The height of the bumps is determined in accordance with their lateral size, and is chosen in accordance with the bonding process by which the bumps are to be connected to corresponding bumps or contact pads on another component.

The deposition of the SC layer 8 prior to depositing the Cu layer 9 is desirable in the case of indium solder bumps 17 and Al contact pads 5, to serve as a diffusion barrier. When the contact pads 5 are formed of an inert SC material such as TiN or NbN, no barrier layer is needed and the Cu layer 9 can be deposited directly on the contact pads 5. The Cu is then removed locally as described above according to any embodiment of the present disclosure, and the indium bumps 17 are formed by electrodeposition directly on the contact pads 5.

A SC qubit component provided with SC solder bumps 17 produced according to a method of the present disclosure can be bonded to another component by a variety of bonding processes. The component may be a qubit chip obtained by dicing the above-described qubit wafer, wherein the chip is bonded to an interposer chip, equally obtained from the wafer or from another wafer. Another scenario may involve an interposer chip that is bonded to a PCB board, or a chip that is bonded to a full wafer in a die-to-wafer bonding process, or full wafers being bonded in a wafer-to-wafer bonding process. All of these bonding processes involve the alignment of the solder bumps on one component to similar bumps or to contact pads on the other component, followed by the interconnection and heating of the aligned bumps or of the aligned bumps and contact pads so that the solder material melts or softens and forms a solid connection after cooling.

During bonding, it is important to control the distance between two bonded components. This can include the inclusion of spacer bumps on the two components. These are bumps formed of a hard material, i.e. a material that does not melt or soften at the melting temperature of the solder bumps, and which are aimed at defining the final distance between the components as they are brought together. This distance is defined by the spacer bumps coming into mutual contact and stopping a further mutual approach of the components. The spacer bumps are distributed across the full surface of the component, for example including at least some spacer bumps in the vicinity of the outer edge of at least one of the components.

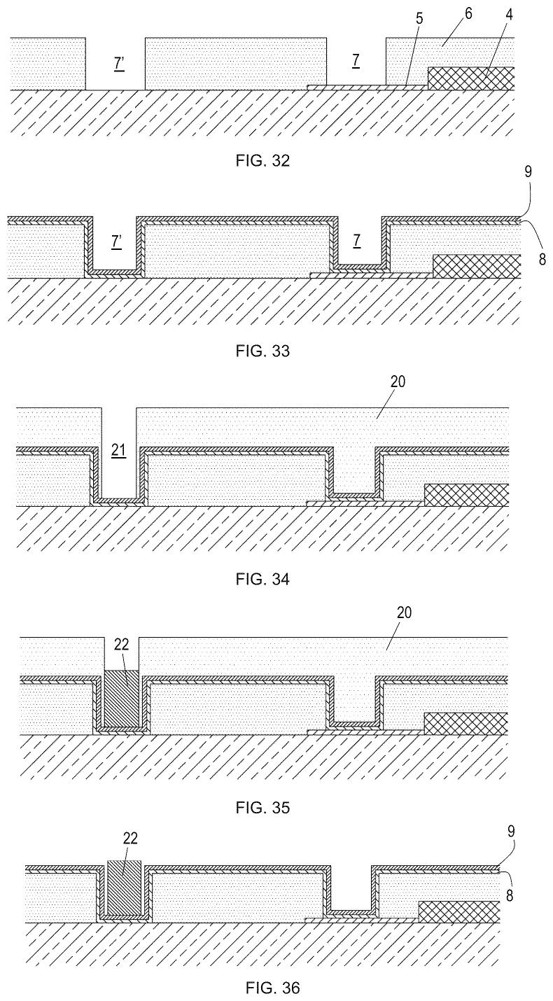

The spacer bumps can be produced by a variety of methods, including by electrodeposition. One example of a way in which this can be realized is illustrated with reference to FIGS. 32-37. These images illustrate the production of spacer bumps as well as solder bumps on a qubit wafer, wherein the solder bumps are produced according to the embodiment of FIGS. 4-14. As seen in FIG. 32, a plurality of additional openings 7′ are formed in the protection layer 6, at the intended locations of the spacer bumps. In the example shown, the diameters of the additional openings 7′ is the same as the diameter of the openings 7, but these diameters may be different from each other.

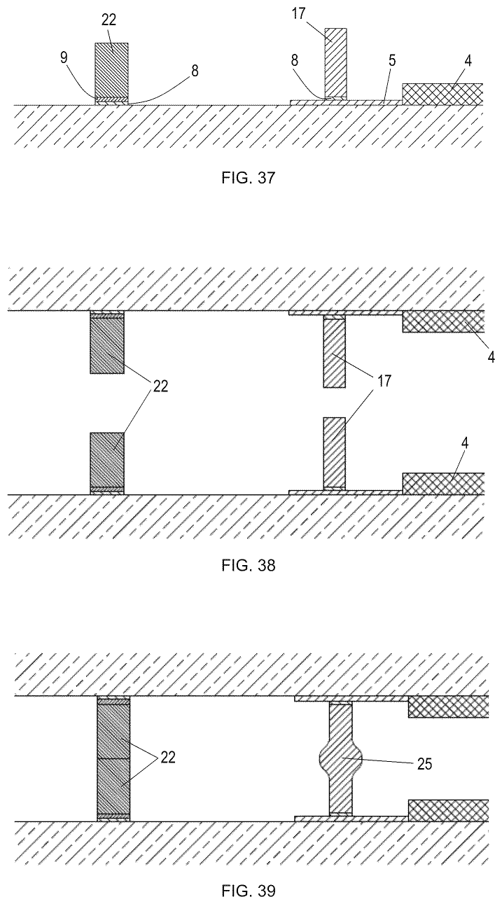

Then (as shown in FIG. 33) the barrier layer 8 and the Cu layer 9 are deposited as in the first embodiment. These layers now conformally cover the sidewalls and the bottom of the additional openings 7′. A mask layer 20 is then formed and patterned, see FIG. 34, comprising openings 21 whose surface area lies within the surface area of the openings 7′. The bottom of the openings 21 is formed by a central portion of the Cu layer 9. This is followed, in some examples, by a cleaning step such as an O₂ plasma treatment for removing resist residuals and rendering the mask layer 20 hydrophilic. Then electrodeposition of the spacer bump material, for example copper is performed, forming Cu spacer bumps 22 in the openings 21, as illustrated in FIG. 35. The mask layer 20 is then stripped, see FIG. 36. After this, the indium bumps 17 are produced by the steps illustrated in FIGS. 7 to 14, resulting in the image shown in FIG. 37: indium solder bumps 17 and Cu spacer bumps 22 are formed on the wafer surface. The solder bumps 17 are higher than the spacer bumps 22. This may be done so that solder bumps can melt or soften and merge to a certain extent, before the spacer bumps define the final distance between the two bonded components. This bonding process is illustrated in FIGS. 38 and 39: first the components are aligned (FIG. 38). Then the bonding takes place (FIG. 39), resulting in a solder connection 25 formed of the merged solder bumps, and with the spacer bumps 22 in head-to-head contact.

Spacer bumps 22 may be included when the solder bumps 17 are small in size. When the solder bumps are in the higher part of the range described above, e.g. 30-50 μm in diameter, it may be possible to omit spacer bumps as the softened solder bumps may be able to provide sufficient stability during bonding so that the distance between the components can be sufficiently controlled. Therefore, the embodiments of the present disclosure are not limited to configurations including spacer bumps.

While the subject matter of the present disclosure has been illustrated and described in detail in the drawings and foregoing description, such illustration and description are to be considered illustrative or exemplary and not restrictive. Other variations to the disclosed embodiments can be understood and effected by those skilled in the art from a study of the drawings, the disclosure, and the appended claims. In the claims, the word “comprising” does not exclude other elements or steps, and the indefinite article “a” or “an” does not exclude a plurality. The mere fact that certain measures are recited in mutually different dependent claims does not indicate that a combination of these measures cannot be used to advantage. Any reference signs in the claims should not be construed as limiting the scope.

Unless specifically specified, the description of a layer being present, deposited or produced ‘on’ another layer or substrate, includes the options of: (i) the layer being present, produced or deposited directly on, i.e. in physical contact with, the other layer or substrate, and (ii) the layer being present, produced or deposited on one or a stack of intermediate layers between the layer and the other layer or substrate

In the claims as well as in the description of this disclosure, the word “comprising” does not exclude other elements or steps and the indefinite article “a” or “an” does not exclude a plurality. A single element may fulfill the functions of several entities or items recited in the claims. The mere fact that certain measures are recited in the mutual different dependent claims does not indicate that a combination of these measures cannot be used in an advantageous implementation.

While various embodiments of the present disclosure have been described above, it should be understood that they have been presented by way of example only, and not limitation. Numerous changes to the disclosed embodiments can be made in accordance with the disclosure herein without departing from the spirit or scope of the present disclosure. Thus, the breadth and scope of the present disclosure should not be limited by any of the above described embodiments.

Although the embodiments described herein have been illustrated and described with respect to one or more implementations, equivalent alterations and modifications will occur to others skilled in the art upon the reading and understanding of this specification and the annexed drawings. In addition, while a particular feature of the present disclosure may have been disclosed with respect to only one of several implementations, such feature may be combined with one or more other features of the other implementations as may be desired for any given or particular application.

What is claimed is:

1. A method for producing solder bumps formed of a superconducting solder material on a substrate, the substrate comprising:
a plurality of superconducting qubits or parts thereof; and
a plurality of contact pads comprising superconducting material, each pad being electrically connected to one or more of the qubits or qubit parts,
and the method comprising:
producing a protection layer on the substrate and patterning the protection layer such that the qubits or qubit parts are covered by the protection layer and further such that the contact pads are at least partially exposed, wherein the patterned protection layer has a given topography;
producing a non-superconducting seed layer on the substrate, the seed layer following the topography of the patterned protection layer, the seed layer being an electrically conductive layer configured to conduct current in an electrodeposition process;
producing a mask layer on the seed layer and patterning the mask layer to form openings therein, the surface area of the openings lying within respective exposed areas of the contact pads;
removing the material of the seed layer from the bottom of the openings;
thereafter, depositing the superconducting solder material by electrodeposition on the bottom of the respective openings, thereby forming the solder bumps;
removing the mask layer; and
after the electrodeposition, removing the seed layer and the protection layer.

2. The method of claim 1, wherein the electrodeposition step is performed after the removal of the material of the seed layer from the bottom of the openings such that the seed layer contacts the bumps in a peripheral area thereof, and wherein the mask layer is removed after the formation of the solder bumps.

3. The method of claim 1, wherein:
the mask layer is a first mask layer and the openings formed therein are first openings,
the first mask layer is removed after the step of removing the material of the seed layer from the bottom of the first openings,
after removing the first mask layer, a second mask layer is produced, wherein the second mask layer is patterned to form second openings therein, the surface area of the second openings lying within the surface area of the respective first openings such that the seed layer is separated from the bottom of the second openings by the material of the second mask layer,
the electrodeposition step is performed after the formation and patterning of the second mask layer on the bottom of the second openings to form solder bumps that are not in contact with the seed layer, and
the second mask layer is removed after the formation of the solder bumps, followed by the removal of the seed layer and the protection layer.

4. The method of claim 1, further comprising producing a layer of superconducting material on the substrate after the formation and patterning of the protection layer and prior to the formation of the seed layer, the layer of superconducting material following the topography of the patterned protection layer such that the layer of superconducting material is exposed at the bottom of the openings, wherein the solder material is deposited on the layer of superconducting material, and wherein the layer of superconducting material outside the bumps is removed after the removal of the seed layer.

5. The method of claim 4, wherein the layer of superconducting material is a barrier layer configured to stop diffusion of solder material into the contact pads.

6. The method of claim 1, wherein the protection layer is patterned to form openings therein, the surface area of the openings lying within the surface area of the contact pads.

7. The method of claim 6, wherein the surface area of the openings in the mask layer lies within the surface area of the openings in the protection layer.

8. The method of claim 6, wherein the surface area of the openings in the mask layer is larger than the surface area of the openings in the protection layer such that the openings in the mask layer fully overlap the openings in the protection layer.

9. The method of claim 1, wherein the protection layer is patterned to cover only the qubits or parts thereof.

10. The method of claim 1, further comprising producing a plurality of spacer bumps.

11. The method of claim 1, wherein the seed layer comprises copper.

12. The method of claim 1, wherein the solder material comprises indium.

13. A substrate comprising:
a plurality of superconducting qubits or parts thereof;
a plurality of contact pads formed of superconducting material, each pad being electrically connected to one or more of the qubits or qubit parts; and
a plurality of solder bumps comprising a superconducting solder material and disposed on the plurality of contact pads.

14. The substrate of claim 13, wherein the plurality of solder bumps are formed via a process comprising:
producing a protection layer on the substrate and patterning the protection layer such that the qubits or qubit parts are covered by the protection layer and further such that the contact pads are at least partially exposed, wherein the patterned protection layer has a given topography;
producing a non-superconducting seed layer on the substrate, the seed layer following the topography of the patterned protection layer, the seed layer being an electrically conductive layer configured to conduct current in an electrodeposition process;
producing a mask layer on the seed layer and patterning the mask layer to form openings therein, the surface area of the openings lying within respective exposed areas of the contact pads;
removing the material of the seed layer from the bottom of the openings;
thereafter, depositing the superconducting solder material by electrodeposition on the bottom of the respective openings, thereby forming the solder bumps;
removing the mask layer; and
after the electrodeposition, removing the seed layer and the protection layer.

15. The substrate of claim 14, wherein the electrodeposition step is performed after the removal of the material of the seed layer from the bottom of the openings such that the seed layer contacts the bumps in a peripheral area thereof, and wherein the mask layer is removed after the formation of the solder bumps.

16. The substrate of claim 14, wherein the process of formation of the solder bumps further comprises producing a layer of superconducting material on the substrate after the formation and patterning of the protection layer and prior to the formation of the seed layer, the layer of superconducting material following the topography of the patterned protection layer such that the layer of superconducting material is exposed at the bottom of the openings, wherein the solder material is deposited on the layer of superconducting material, and wherein the layer of superconducting material outside the bumps is removed after the removal of the seed layer.

17. The substrate of claim 16, wherein the layer of superconducting material is a barrier layer configured to stop diffusion of solder material into the contact pads.

18. The substrate of claim 14, wherein the seed layer comprises copper.

19. The substrate of claim 13, further comprising a plurality of spacer bumps.

20. The substrate of claim 13, wherein the solder material comprises indium.
